(19) United States
(12) Patent Application Publication
(10) Pub. No.: US 2015/0241269 A1
(43) Pub. Date: Aug. 27, 2015

(54) OPTICAL COMMUNICATION MODULE AND METHOD FOR ASSEMBLING SAME

(71) Applicant: HON HAI PRECISION INDUSTRY CO., LTD., New Taipei (TW)

(72) Inventor: CHIH-CHEN LAI, New Taipei (TW)

(21) Appl. No.: 14/610,194

(22) Filed: Jan. 30, 2015

(30) Foreign Application Priority Data
Feb. 21, 2014 (TW) 103105775

(51) Int. Cl. G01J 1/04; B32B 38/00; B32B 37/12; H05K 3/30; B32B 37/18

(52) U.S. Cl. CPC G01J 1/0411; H05K 3/305; B32B 37/18; B32B 37/12; B32B 38/0008; H05K 2203/1194; B32B 37/1207; B32B 2307/412; B32B 2551/00; B32B 2457/00

(57) ABSTRACT

An optical communication module includes a circuit board, a photoelectric converting unit, and an optical coupler. The circuit board includes a substrate including a first surface and a second surface opposite to the first surface, a hot-curable adhesive layer formed on the first surface, and a metal reflective layer formed on the second surface and aligned with the hot-curable adhesive layer. The photoelectric converting unit is mounted on the first surface. By virtue of the function of the metal reflective layer in the heat curing process, the optical coupler is precisely fixed to the substrate via the hot-curable adhesive layer.

### FIELD

The subject matter herein generally relates to optical communications.

### BACKGROUND

An optical communication module usually includes a circuit board and an optical coupler. Curable glue is usually used to fix the optical coupler to the circuit board. During curing, the curable glue may flow, disturbing the positioning of the optical coupler. Therefore, the optical coupler may not be precisely fixed on the circuit board.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of an optical communication module according to an exemplary embodiment of the present disclosure.

FIG. 2 is an exploded view of the optical communication module of FIG. 1.

FIG. 3 is a top view of a circuit board of the optical communication module of FIG. 2.

FIG. 4 is a cross sectional view along IV-IV line of FIG. 1.

FIG. 5 is a cross sectional view showing the optical communication module of FIG. 1 being heated by a heating device.

FIG. 6 is a flowchart showing an assembling process of the optical communication module of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

The present disclosure is described in relation to an optical communication module and a method for assembling the optical communication module.

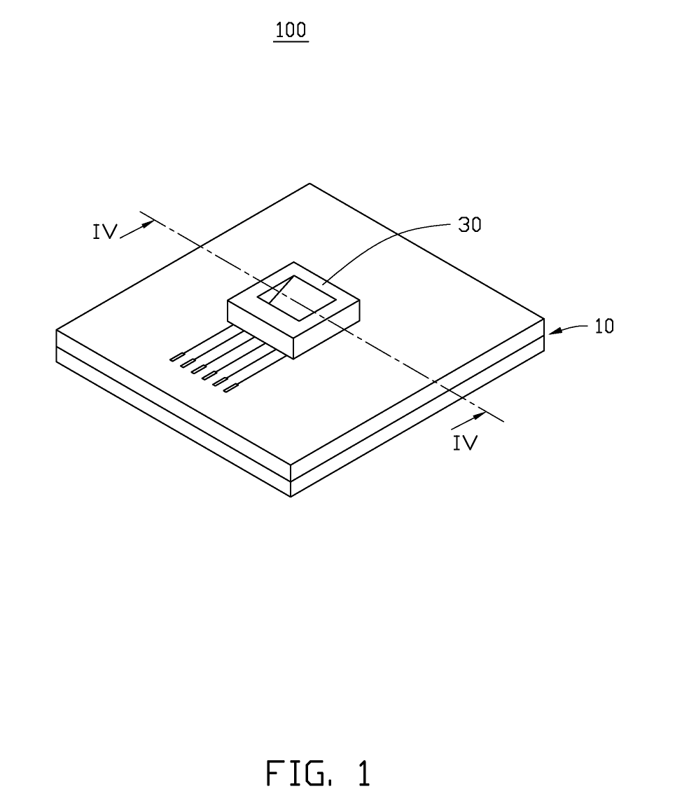

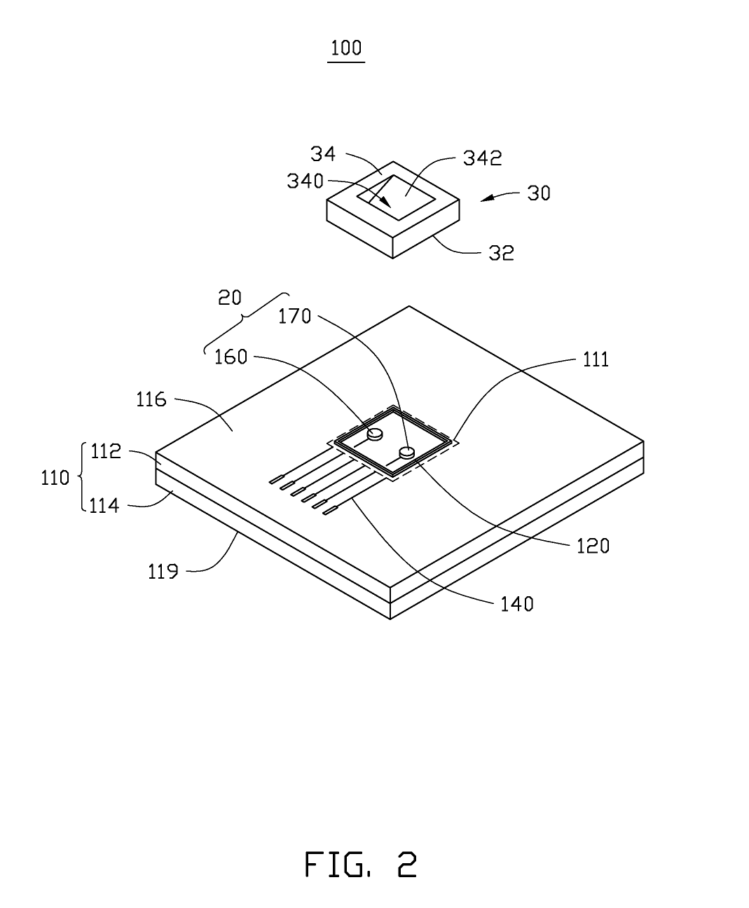

FIGS. 1 and 2 illustrate that an optical communication module 100 can include a circuit board 10, a photoelectric converting unit 20, and an optical coupler 30.

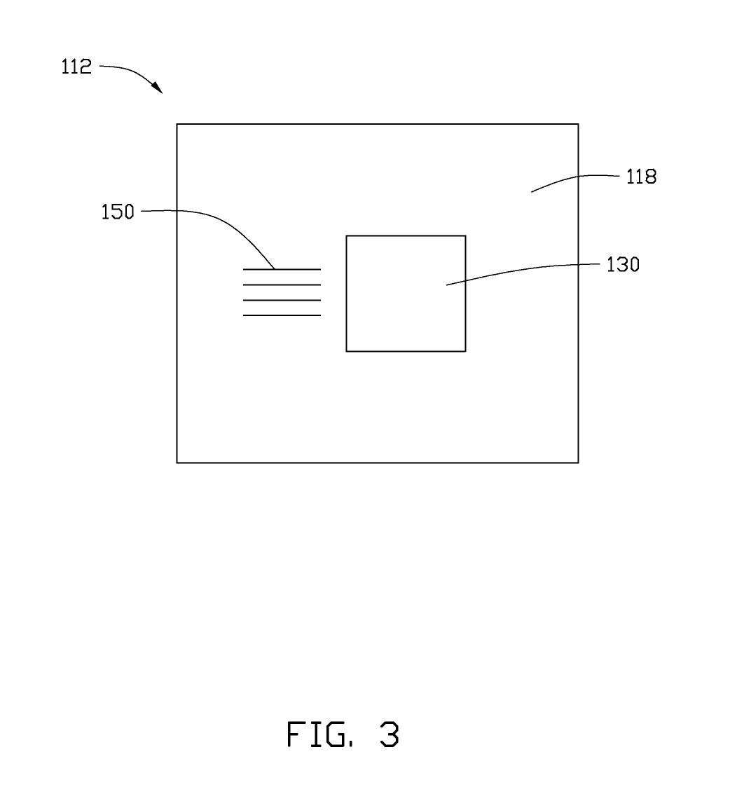

FIGS. 2 through 4 illustrate that the circuit board 10 can include a substrate 110, a hot-curable adhesive layer 120, a metal reflective layer 130, a plurality of first traces 140, and a plurality of second traces 150.

The substrate 110 includes a first layer 112 and a second layer 114 stacked together. In this embodiment, the first layer 112 and the second layer 114 are made of glass fiber. The first layer 112 includes a first surface 116 and an opposite second surface 118. The first and second surfaces 116, 118 are parallel to each other. The second layer 114 includes a third surface 117 and an opposite fourth surface 119. The third surface 117 and the fourth surface 119 are parallel to each other. The second surface 118 is adhered to the third surface 117. The first surface 116 defines a notional rectangular area 111.

The hot-curable adhesive layer 120 is formed on the first surface 116 in the notional rectangular area 111. The hot-curable adhesive layer 120 forms a rectangular frame.

The metal reflective layer 130 is formed on the second surface 118 and is aligned with the hot-curable adhesive layer 120. The metal reflective layer 130 is rectangular. In another embodiment, the metal reflective layer 130 can also be formed on the fourth surface 119.

The photoelectric converting unit 20 includes a light emitting device 160 and a light receiving device 170 both positioned on the first surface 116 in the notional rectangular area 111. The light emitting device 160 emits light and the light receiving device 170 receives light. In this embodiment, the light emitting device 160 is a laser source, and the light receiving device 170 is a photodiode. The light emitting device 160 and the light receiving device 170 are electrically connected to first traces 140. The light emitting device 160, the light receiving device 170, and the first traces 140 are electrically isolated from the hot-curable adhesive layer 120. In this embodiment, the light emitting device 160 and the light receiving device 170 are surrounded by the hot-curable adhesive layer 120, and are respectively connected to the first traces 140 via conductive holes (not shown). The second traces 150 are formed on the second surface 118 and are electrically isolated from the metal reflective layer 130. The second traces 150 are electrically connected to the first traces 140 via conductive holes (not shown).

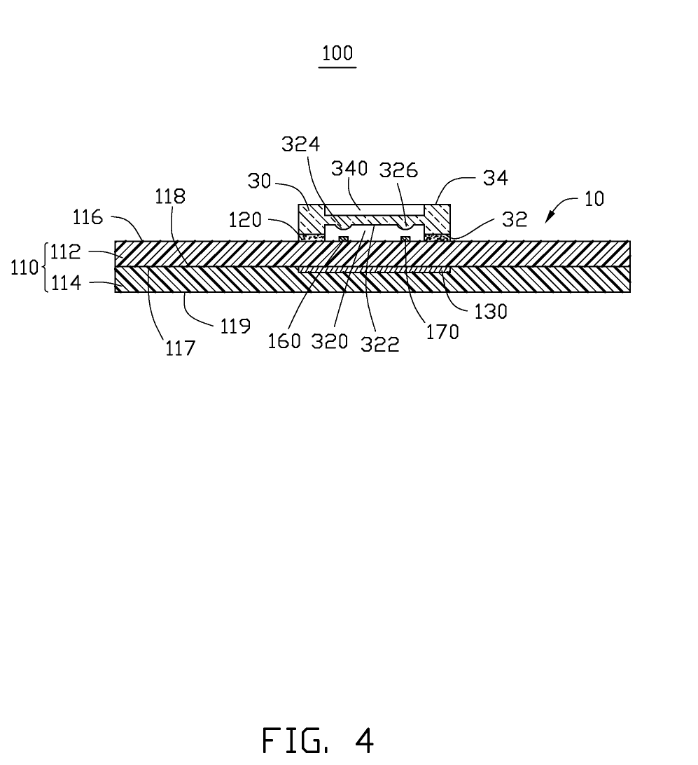

FIGS. 2 and 4 illustrate that the optical coupler 30 includes a bottom surface 32 and a top surface 34 opposite to the bottom surface 32. The bottom surface 32 is adjacent to the substrate 110. The bottom surface 32 defines a bottom groove 320. The bottom groove 320 includes an optical surface 322 parallel to the bottom surface 32. The top surface 34 defines a top groove 340 aligned with the bottom groove 320. The top groove 340 includes a reflective surface 342 tilted about 45 degrees relative to the bottom surface 32. The bottom surface 32 is connected to the first surface 116 via the hot-curable adhesive layer 120. The optical coupler 30 further includes a first optical lens 324 and a second optical lens 326 formed on the optical surface 322. The first optical lens 324 is aligned with the light emitting device 160. The second optical lens 326 is aligned with the light receiving device 170.

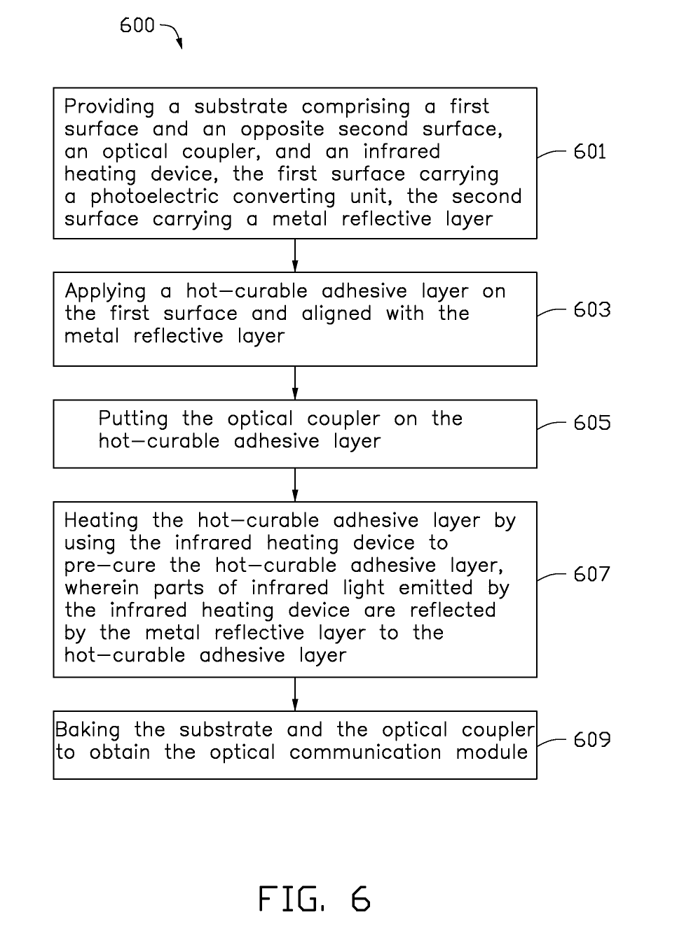

Referring to FIG. 6, a flowchart is presented in accordance with embodiment which is being thus illustrated. The method 600 is provided by way of example, as there are a variety of ways to carry out the method. The method 600 described below can be carried out using the configurations illustrated in FIGS. 1-5, for example, and various elements of these figures are referenced in explaining example method 600. Each block shown in FIG. 6 represents one or more processes, methods, or subroutines, carried out in the exemplary method 600. Furthermore, the illustrated order of blocks is by example only and the order of the blocks can change. Additional blocks may be added or fewer blocks may be utilized, without departing from this disclosure. The exemplary method 600 can begin at block 601.

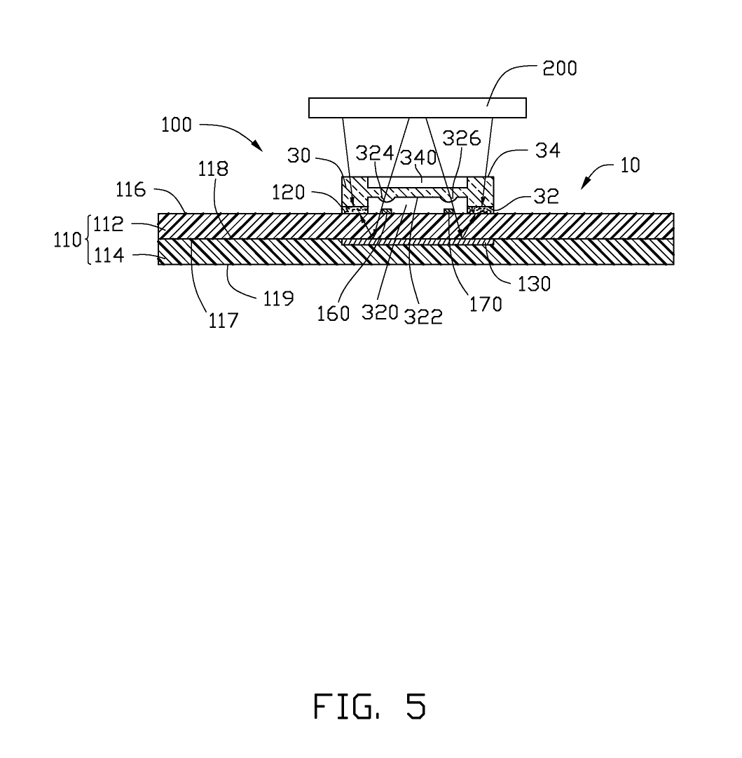

At block 601, as shown in FIG. 5, a substrate 110, an optical coupler 30, and a heating device 200 are provided. In this embodiment, the heating device 200 is an infrared heating device.

At block 603, hot-curable adhesive glue is applied on the first surface 116 to form the hot-curable adhesive layer 120.

At block 605, the optical coupler 30 is put on the hot-curable adhesive layer 120, the first optical lens 324 is aligned with the light emitting device 160, and the second optical lens 326 is aligned with the light receiving device 170.

At block 607, the heating device 200 is put at on one side of the substrate 110 adjacent to the first surface 116, and emits infrared light to heat and pre-cure the hot-curable adhesive layer 120. In this embodiment, the infrared light transmitted through the first layer 112 is reflected by the metal reflective layer 130 and heats the hot-curable adhesive layer 120 again. In this way, a heating efficiency is improved.

At block 609, the substrate 110 and the optical coupler 30 are baked to fully cure the hot-curable adhesive layer 120, and the optical communication module 100 is obtained.

The hot-curable adhesive layer 120 can be pre-cured by using the heating device 200 and the metal reflective layer 130. Thus, the hot-curable adhesive layer 120 will not flow during the process of baking and the positioning of the optical coupler 30 will not be disturbed on the circuit board 10.

It will be understood that the above particular embodiments are shown and described by way of illustration only. The principles and the features of the present disclosure can be employed in various and numerous embodiments thereof without departing from the scope of the disclosure. The above-described embodiments illustrate the scope of the disclosure but do not restrict the scope of the disclosure.

What is claimed is:

1. An optical communications module comprising:
a circuit board with a first substrate layer having a first surface and a second surface opposite, and substantially parallel to, the first surface, a hot-curable adhesive layer formed on a portion of the first layer surface, and a metal reflective layer formed on the second surface substantially opposite and aligned with the hot-curable layer;
an optical coupler coupled to the first substrate surface; and
a photo-electrical converting unit mounted on the first substrate layer;
wherein, the hot-curable adhesive couples the optical coupler to the first substrate layer.

2. The optical communication module of claim 1, wherein the circuit board further comprises a plurality of first traces formed on the first surface, the photoelectric converting unit further comprises a light emitting device and a light receiving device both electrically connected to the first traces.

3. The optical communication module of claim 2, wherein the circuit board further comprises a plurality of second traces formed on the second surface, electrically connected to the first traces, and electrically isolated from the metal reflective layer.

4. The optical communication module of claim 2, wherein the optical coupler comprises a first optical lens aligned with the light emitting device, and a second optical lens aligned with the light receiving device.

5. The optical communication module of claim 1, wherein the substrate comprises a first layer and a second layer stacked together, the first layer comprises the first surface and the second surface.

6. A method for assembling an optical communication module, comprising:
providing a substrate comprising a first surface and an opposite second surface, an optical coupler, and an infrared heating device, the first surface carrying a photoelectric converting unit, the second surface carrying a metal reflective layer;
applying a hot-curable adhesive layer on the first surface and aligned with the metal reflective layer;
putting the optical coupler on the hot-curable adhesive layer;
heating the hot-curable adhesive layer by using the infrared heating device to pre-cure the hot-curable adhesive layer, wherein parts of infrared light emitted by the infrared heating device are reflected by the metal reflective layer to the hot-curable adhesive layer; and
baking the substrate and the optical coupler to obtain the optical communication module.

7. The method of claim 6, wherein the circuit board further comprises a plurality of first traces formed on the first surface, the photoelectric converting unit further comprises a light emitting device and a light receiving device both electrically connected to the first traces.

8. The method of claim 7, wherein the circuit board further comprises a plurality of second traces formed on the second surface, electrically connected to the first traces, and electrically isolated from the metal reflective layer.

9. The method of claim 7, wherein the optical coupler comprises a first optical lens aligned with the light emitting device, and a second optical lens aligned with the light receiving device.

10. The method of claim 6, wherein the substrate comprises a first layer and a second layer stacked together, the first layer comprises the first surface and the second surface.
